(19) United States
(12) Patent Application Publication
(10) Pub. No.: US 2025/0122643 A1
(43) Pub. Date: Apr. 17, 2025

(54) METHOD FOR PRODUCING GROUP III NITRIDE SEMICONDUCTOR

(71) Applicants: TOYODA GOSEI CO., LTD., Kiyosu-shi (JP); MEIJO UNIVERSITY, Nagoya-shi (JP)

(72) Inventors: Koji OKUNO, Kiyosu-shi (JP); Yoshiki SAITO, Kiyosu-shi (JP); Tetsuya TAKEUCHI, Nagoya-shi (JP); Satoshi KAMIYAMA, Nagoya-shi (JP); Motoaki IWAYA, Nagoya-shi (JP); Hisanori ISHIGURO, Nagoya-shi (JP); Tomoaki KACHI, Nagoya-shi (JP)

(21) Appl. No.: 18/910,990

(22) Filed: Oct. 9, 2024

(30) Foreign Application Priority Data
Oct. 11, 2023 (JP) 2023-176098

(51) Int. Cl. C30B 29/40; C30B 25/10; C30B 25/18; C30B 28/14

(52) U.S. Cl. CPC C30B 29/406; C30B 25/10; C30B 25/18; C30B 28/14

(57) ABSTRACT

A method for producing a Group III nitride semiconductor, includes: performing an ammonia treatment of supplying a gas containing ammonia to a surface of a substrate containing sapphire; subjecting the surface of the substrate to a heat treatment in a hydrogen-dominated atmosphere, after the ammonia treatment; nitriding the surface of the substrate by supplying a gas containing ammonia to the surface of the substrate, after the subjecting; and forming a crystal nucleus layer on the substrate by generating nuclei of GaN, AlGaN or AlN on the substrate, after the nitriding.

### CROSS-REFERENCE TO RELATED APPLICATION

This application is based on and claims priority under 35 USC 119 from Japanese Patent Application No. 2023-176098 filed on Oct. 11, 2023.

### TECHNICAL FIELD

The present invention relates to a method for producing a Group III nitride semiconductor.

### BACKGROUND ART

A wavelength of an ultraviolet ray from a solid-state light emitting element using a Group III nitride semiconductor corresponds to a wavelength band in a range of about 210 nm to 400 nm. In particular, it is known that UVC (wavelength of 100 nm to 280 nm) can efficiently sterilize and eliminate bacteria, and there is an increasing demand for a Group III nitride semiconductor light emitting element that emits ultraviolet light having an emission wavelength corresponding to that of the UVC. The ultraviolet LED has a structure in which an AlN layer is formed on a sapphire substrate, and an n layer, a light emitting layer, and a p layer made of AlGaN are stacked on the AlN layer.

In order to form a high-quality AlN layer, it is necessary to nitride a surface of the sapphire substrate before growing AlN. Non Patent Literature 1 discloses that ammonia is supplied to a sapphire substrate to nitride the sapphire substrate, and then AlN is formed on the sapphire substrate. In addition, it is disclosed that the nitriding treatment is performed by increasing the temperature from a low temperature to 1200° C.

### CITATION LIST

Non Patent Literature 1: Mitsuru Funato, Mami Shibaoka and Yoichi Kawakami, “Heteroepitaxy mechanisms of AlN on nitridated c- and a-plane sapphire”, JOURNAL OF APPLIED PHYSICS 121, 085304 (2017)

### SUMMARY OF INVENTION

However, in the method in Non Patent Literature 1, a nitride film (AlN) formed by the nitriding treatment is a crystal having a mixture of a +c plane and a −c plane, and there are problems such as deterioration in quality of the crystal formed on AlN, and difficulty in controlling crack generation and surface roughness.

The present invention has been made in view of such a circumstance, and an object thereof is to provide a method for producing a Group III nitride semiconductor capable of forming a Group III nitride semiconductor having a good crystal quality.

An aspect of the present invention is directed to a method for producing a Group III nitride semiconductor, comprising:
an ammonia treatment step of supplying a gas containing ammonia to a surface of a substrate made of sapphire;
a thermal cleaning step of subjecting the surface of the substrate to a heat treatment in a hydrogen-dominated atmosphere, after the ammonia treatment step;
a nitriding treatment step of nitriding the surface of the substrate by supplying a gas containing ammonia to the surface of the substrate, after the thermal cleaning step; and
a crystal nucleus layer forming step of forming a crystal nucleus layer on the substrate by generating nuclei of GaN, AlGaN, or AlN on the substrate, after the nitriding treatment step.

In the above aspect, the sapphire substrate is subjected to an ammonia treatment before thermal cleaning, and the surface of the sapphire substrate is nitrided after the thermal cleaning. Therefore, the crystal quality of a Group III nitride semiconductor formed on the sapphire substrate can be improved.

### BRIEF DESCRIPTION OF DRAWINGS

FIG. 1 is a diagram showing a process for producing a Group III nitride semiconductor according to a first embodiment.

FIGS. 2A, 2B, 2C, 2D, and 2E are schematic diagrams each showing a layer configuration at each growth stage in the first embodiment.

FIG. 3 is a graph showing a change in temperature and pressure over time in the first embodiment.

FIG. 4 is a graph showing a relationship between a temperature range in an ammonia treatment and a full width at half maximum of a diffraction line in X-ray diffraction.

FIG. 5 is a graph showing a relationship between an ammonia treatment time and the full width at half maximum of the diffraction line in the X-ray diffraction.

FIG. 6 is a graph showing a relationship between a start temperature in the ammonia treatment and the full width at half maximum of the diffraction line in the X-ray diffraction.

FIG. 7 is a graph showing a relationship between a flow rate of hydrogen in thermal cleaning and a full width at half maximum of a diffraction line in X-ray diffraction.

FIG. 8 is a graph showing a relationship between a nitriding treatment time and a full width at half maximum of a diffraction line in X-ray diffraction.

FIGS. 9A, 9B, 9C, and 9D are schematic diagrams each showing a layer configuration at each growth stage in a second embodiment.

FIG. 10 is a graph showing a change in temperature over time in the second embodiment.

FIG. 11 is a graph comparing full widths at half maximum of a (002) diffraction line.

FIG. 12 is a graph comparing full widths at half maximum of a (102) diffraction line.

### DESCRIPTION OF EMBODIMENTS

A method for producing a Group III nitride semiconductor includes: an ammonia treatment step of supplying a gas containing ammonia to a surface of a substrate made of sapphire; a thermal cleaning step of subjecting the surface of the substrate to a heat treatment in a hydrogen-dominated atmosphere, after the ammonia treatment step; a nitriding treatment step of nitriding the surface of the substrate by supplying a gas containing ammonia to the surface of the substrate, after the thermal cleaning step; and a crystal nucleus layer forming step of forming a crystal nucleus layer on the substrate by generating nuclei of GaN, AlGaN, or AlN on the substrate, after the nitriding treatment step.

In the above method for producing a Group III nitride semiconductor, the ammonia treatment step may be performed at a temperature of 20° C. or higher and 900° C. or lower. The crystal quality of the crystal nucleus layer can be further improved.

In the above method for producing a Group III nitride semiconductor, the ammonia treatment step may be performed for a period of time of 1 second or longer and 60 seconds or shorter. The crystal quality of the crystal nucleus layer can be further improved.

In the above method for producing a Group III nitride semiconductor, the ammonia treatment step may be performed under an ammonia partial pressure of 0.001 atm or more and 0.1 atm or less and at a gas linear velocity of 0.01 m/min or more and 300 m/min or less. The crystal quality of the crystal nucleus layer can be further improved.

In the above method for producing a Group III nitride semiconductor, the thermal cleaning step may be performed at a temperature higher than 900° C. The crystal quality of the crystal nucleus layer can be further improved.

In the above method for producing a Group III nitride semiconductor, the nitriding treatment step may be performed at a temperature equal to or lower than a temperature in the thermal cleaning step for 50 seconds or longer. The crystal quality of the crystal nucleus layer can be further improved.

The above method for producing a Group III nitride semiconductor may further include: a low-temperature three-dimensional growth layer forming step of forming a low-temperature three-dimensional growth layer by growing AlGaN or AlN from the nucleus at a temperature lower than a temperature in the crystal nucleus layer forming step and combining crystals from adjacent nuclei, after the crystal nucleus layer forming step; and a high-temperature three-dimensional growth layer forming step of forming a high-temperature three-dimensional growth layer by growing AlGaN or AlN from the low-temperature three-dimensional growth layer at a temperature higher than the temperature in the low-temperature three-dimensional growth layer forming step and equal to or lower than the temperature in the crystal nucleus layer forming step, after the low-temperature three-dimensional growth layer forming step. AlGaN or AlN having a good crystal quality can be formed.

### First Embodiment

### 1. Method for Producing Group III Nitride Semiconductor

A method for producing a Group III nitride semiconductor according to a first embodiment will be described. Note that, a Group III nitride semiconductor is formed using an MOCVD method, and as a raw material gas, for example, ammonia is used as a raw material gas for nitrogen, trimethylgallium (TMGa) or triethylgallium (TEGa) is used as a raw material gas for Ga, trimethylaluminum (TMAl) is used as a raw material gas for Al, and hydrogen or nitrogen is used as a carrier gas.

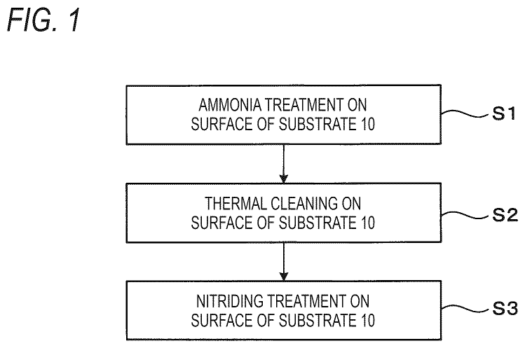

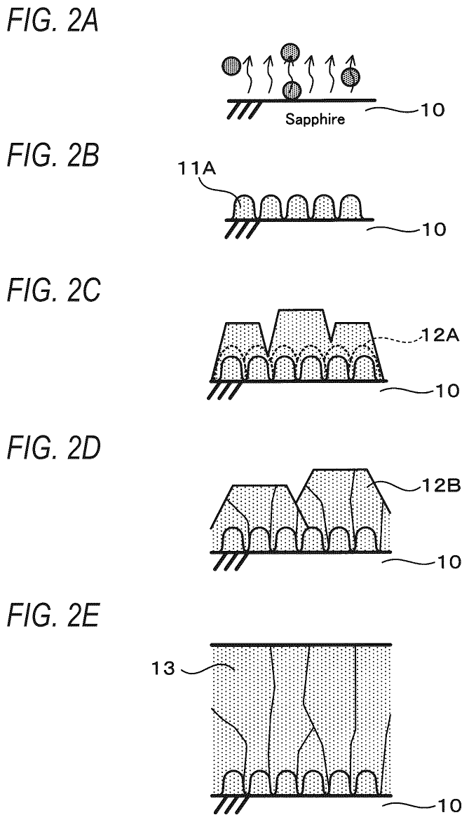

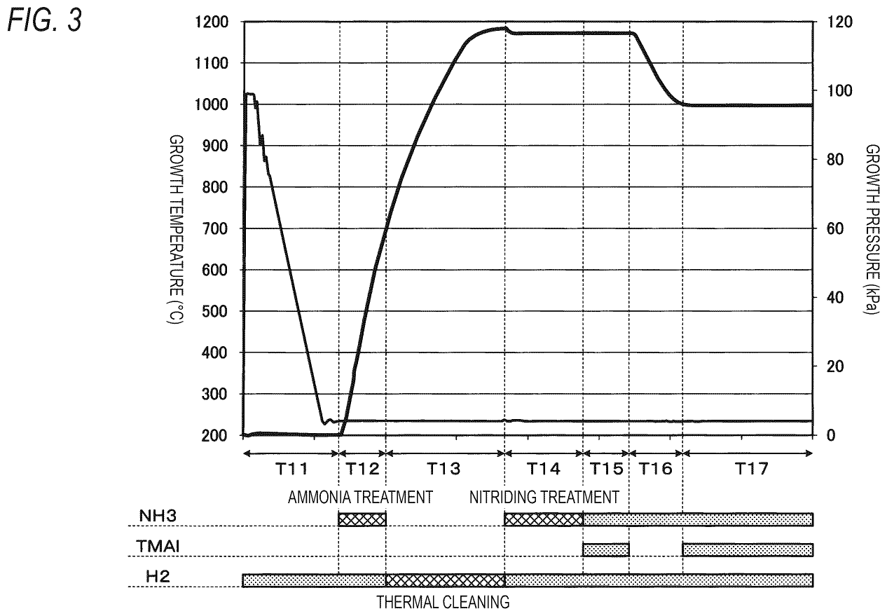

In the following description of the production method, reference will be made to FIG. 1, FIGS. 2A, 2B, 2C, 2D and 2E, and FIG. 3 as appropriate. FIG. 1 is a flowchart showing an initial step (step before formation of nuclei 11A) in a process for producing a Group III nitride semiconductor. FIGS. 2A, 2B, 2C, 2D, and 2E are diagrams each schematically showing a layer configuration in each growth stage up to formation of a two-dimensional growth layer 13. FIG. 3 is a graph showing a change in temperature and pressure over time, and supply timings of various gases.

### 1-1. Ammonia Treatment Step

First, a substrate 10 made of sapphire and having a c plane as a main surface is prepared. The main surface may be an a plane. It may have an off angle of 0.1 to 2 degrees in an m-axis direction or an a-axis direction.

Next, the substrate 10 is disposed in an MOCVD apparatus, and the apparatus is evacuated and purged with hydrogen (or nitrogen) to reduce the pressure in the MOCVD apparatus (a period T11 in FIG. 3). In FIG. 3, a case where the pressure is 4 kPa is shown.

Thereafter, the surface of the substrate 10 is subjected to an ammonia treatment (step S1 in FIG. 1, a period T12 in FIG. 3). The ammonia treatment is a treatment in which ammonia is added to hydrogen to form a mixed gas, which is then supplied to the MOCVD apparatus, and the substrate 10 is heated to bring the surface of the substrate 10 into an ammonia atmosphere. In FIG. 3, a case where the treatment is performed while increasing the temperature from 200° C. to 700° C. at a pressure of 4 kPa is shown as an example of the ammonia treatment.

The temperature (substrate temperature) at the start of the supply of ammonia may be room temperature (for example, 20° C.) or higher and lower than 900° C. In the first embodiment, the ammonia treatment is performed while increasing the temperature, and the maximum temperature is preferably 900° C. or lower.

Note that, in the first embodiment, the ammonia treatment is performed while increasing the temperature, but may be performed at a constant temperature as long as the temperature is room temperature or higher and 900° C. or lower. When the ammonia treatment is performed at a constant temperature, the treatment is more preferably performed at 20° C. to 900° C. When the ammonia treatment is performed while increasing the temperature, the start temperature is preferably 20° C. to 900° C., and the final temperature is preferably 200° C. to 900° C.

The ammonia treatment time is preferably 1 second to 60 seconds. Within this range, the crystal quality of a crystal nucleus layer 11 can be further improved. The ammonia treatment time is more preferably 10 seconds to 50 seconds.

It is thought that some modification occurs on the surface of the substrate 10 due to the ammonia treatment, since ammonia is corrosive. In addition, since the treatment is performed at a low temperature of 900° C. or lower, the efficiency of decomposing ammonia is low, and there is a possibility that the surface of the substrate 10 is not sufficiently nitrided.

In the ammonia treatment, an ammonia partial pressure is preferably 0.001 atm to 0.1 atm, and a gas flow rate is preferably 0.01 m/min to 300 m/min. Within these ranges, the crystal quality of the crystal nucleus layer 11 formed on the substrate 10 can be further improved. The ammonia partial pressure is more preferably 0.01 atm to 0.05 atm, and the gas flow rate is more preferably 0.1 m/min to 150 m/min.

The pressure in the ammonia treatment may be a normal pressure, and a reduced pressure is preferred, for example, 1 kPa to 90 kPa, preferably 1 kPa to 50 kPa, and more preferably 1 kPa to 20 kPa. The pressure may be the same as that in the subsequent thermal cleaning step.

In the first embodiment, a mixed gas of hydrogen and ammonia is used, but an inert gas such as nitrogen may be mixed instead of or in addition to hydrogen.

### 1-2. Thermal Cleaning Step

Next, the surface of the substrate 10 is subjected to thermal cleaning (step S2 in FIG. 1, a period T13 in FIG. 3). The thermal cleaning is performed by continuing heating the substrate 10 while stopping the supply of ammonia and supplying only hydrogen. With the thermal cleaning, impurities adhering to the surface of the substrate 10 are removed, and the surface of the substrate 10 is flattened (see FIG. 2A). It is thought that, with the thermal cleaning, impurities such as oxides and Si are released from the surface of the substrate 10, and an Al₂O₃ surface of sapphire becomes an Al-rich surface.

The thermal cleaning is preferably performed at a temperature higher than 900° C. For example, the thermal cleaning is performed at a temperature of 1150° C. to 1300° C. for 1 second to 15 minutes. The thermal cleaning may be performed while increasing the temperature or at a constant temperature. In FIG. 3, a case where thermal cleaning is performed while increasing the temperature from 700° C. to 1190° C. at a pressure of 4 kPa is shown as an example of the thermal cleaning.

The temperature in the thermal cleaning is preferably higher than the temperature in the crystal nucleus layer forming step to be described later. The temperature in the thermal cleaning is in the range of more preferably 1170° C. to 1250° C., and still more preferably 1180° C. to 1220° C. The atmosphere may be a hydrogen-dominated atmosphere, for example, a mixed gas containing 80 vol % or more of hydrogen. The mixed gas is, for example, a mixed gas of hydrogen and nitrogen.

The pressure may be a normal pressure, and a reduced pressure is preferred, for example, 1 kPa to 90 kPa, preferably 1 kPa to 50 kPa, and more preferably 1 kPa to 20 kPa.

A flow rate of a hydrogen gas or a mixed gas of hydrogen and nitrogen on the substrate 10 may be 5 m/min (meters per minute) to 500 m/min, preferably 5 m/min to 300 m/min, and more preferably 5 m/min to 150 m/min. The flow rate in a mass flow controller is preferably 1 slm to 30 slm. The amount of cracks in the two-dimensional growth layer 13 can be reduced.

### 1-3. Nitriding Treatment Step

Next, the surface of the substrate 10 is subjected to a nitriding treatment (step S3 in FIG. 1, a period T14 in FIG. 3). The nitriding treatment is a treatment in which the Al-rich surface of the substrate 10 is nitrided by supplying ammonia in addition to hydrogen at a temperature lower than that in the thermal cleaning. With the nitriding treatment, on the surface of the substrate 10, an AlN layer (not shown) of one to several monolayers is formed, which serves as a starting point for nucleation. In FIG. 3, a case where the treatment is performed at a pressure of 4 kPa and a temperature of 1155° C. is shown as an example of the nitriding treatment.

The temperature in the nitriding treatment is, for example, 1100° C. to 1220° C., which may be the same as the temperature in the subsequent crystal nucleus layer forming step. The pressure in the nitriding treatment is the same as that in the ammonia treatment and the thermal cleaning. In addition, the ammonia partial pressure and the gas flow rate may be the same as those in the ammonia treatment. The nitriding treatment time is preferably 50 seconds or longer. The amount of cracks in the two-dimensional growth layer 13 can be reduced. The nitriding treatment time is more preferably 70 seconds to 300 seconds.

### 1-4. Crystal Nucleus Layer Forming Step

Next, ammonia and TMAl are supplied at a temperature same as that in the previous nitriding treatment step or at a temperature lower than that in the previous nitriding treatment step, and the nuclei 11A of AlN are generated on the substrate 10 to form the crystal nucleus layer 11 (FIG. 2B, a period T15 in FIG. 3). In FIG. 3, a case at a temperature of 1155° C. is shown as an example. The pressure is the same as in the previous step. In the conventional art, the nuclei 11A are formed at about 1000° C. In the first embodiment, by setting the temperature higher than this, the surface migration of the raw material atoms is enhanced, and the nuclei 11A are formed larger than those in the conventional art. Accordingly, the nuclei 11A made of AlN can have a high quality.

A lattice mismatch difference between the nuclei 11A and the substrate 10 made of sapphire causes a compressive stress in the crystal nucleus layer 11. However, since the lattice mismatch difference between the nuclei 11A and the substrate 10 is large, the stress is relaxed within a few nm, and a stress at an interface between the substrate 10 and the nuclei 11A is small.

The crystal nucleus layer 11 is preferably grown to a thickness of 1 nm to 100 nm. The nuclei 11A can be sufficiently enlarged. In addition, the size and the density of the nuclei 11A are preferably within the following ranges.

The density of the nuclei 11A is preferably 3×10¹¹/cm⁻² or less. The size (average diameter in a plan view) of the nuclei 11A is preferably 20 nm to 50 nm. Here, the diameter is a diameter when the nuclei 11A are each converted into a circle of the same area. When the size of the nuclei 11A is within this range, the tensile stress can be sufficiently reduced. In addition, a variation in size of the nuclei 11A (a difference between a maximum diameter and the average diameter, and a difference between the average diameter and a minimum diameter) is preferably 10 nm or less.

It is important that the nuclei 11A are large. When the crystal nuclei are combined to form a flat film, the tensile stress is generated on the surface. Therefore, when the nucleus size is small and the density is large, the stress generated on the surface of the flat film obtained by combining the nuclei is also increased. Therefore, the nucleus density needs to be reduced. Therefore, it is effective to increase the nucleus size.

A small nucleus density has another advantage. Threading dislocations are formed at combining surfaces where the nuclei 11A are combined. A small nucleus density also reduces the amount of the combining surfaces where the nuclei 11A are combined. Therefore, when the nucleus density is reduced, the formation of threading dislocations can be reduced, and a high-quality crystal film can be formed.

The growth temperature of the crystal nucleus layer 11 is preferably 1100° C. to 1200° C. When the temperature is within this range, the nuclei 11 A can be sufficiently enlarged. This is because the surface migration of the raw material atoms can be enhanced. The growth temperature is more preferably 1125° C. to 1190° C., and still more preferably 1150° C. to 1180° C. The temperature may be the same as that in the previous nitriding treatment. When the nuclei 11A are enlarged, the nucleus density is reduced. Therefore, the number of interfaces between the nuclei 11A is also reduced. There is a possibility that the tensile stress is generated in the film when the nuclei 11A are combined to be flat, but by reducing the nucleus density as described above, the stress generated after the nuclei 11A are combined can be reduced.

The growth rate is preferably 5 nm/min to 100 nm/min. When the growth rate is large, the diameter of the nuclei 11A can be increased. The growth rate is more preferably 10 nm/min to 80 nm/min, and still more preferably 20 nm/min to 70 nm/min.

A V/III ratio is preferably 5 to 500. When the V/III ratio is within such a range, the growth rate can be controlled within the above range. The V/III ratio is more preferably 5 to 400, and still more preferably 5 to 300.

Note that, there is a possibility that AlN having a −c plane is formed on the substrate 10 subjected to the nitriding treatment, but is can be made into one having a +c plane by adjusting the growth conditions of the nuclei 11A, such as a small V/III ratio and a large growth rate. Generally, a crystal layer having a +c plane is preferred, and even when the crystal nucleus layer 11 contains a mixture of +c and −c, the proportion of −c is small, and +c is dominant during the growth process, so that the final crystal layer has a surface having only a +c plane. Another possibility is that in the case of 1100° C. or higher, AlON may be formed on the surface of AlN. It is known that AlON reverses the polarity, and it is thought that even when AlN having a −c plane is formed on the substrate 10 subjected to the nitriding treatment, the polarity is reversed by the AlON, resulting in a +c plane.

### 1-5. Low-Temperature Three-Dimensional Growth Layer Forming Step

After the crystal nucleus layer 11 has grown to a predetermined thickness, the supply of TMAl is stopped and cooling is performed to a temperature lower than that in the step of forming the crystal nucleus layer 11 (a period T16 in FIG. 3). Then, cooling is performed to a growth temperature of a low-temperature three-dimensional growth layer 12A, and then the supply of TMAl is resumed. Accordingly, crystals are grown three-dimensionally starting from the nuclei 11A of the crystal nucleus layer 11, and the crystals grown from adjacent nuclei 11A are combined to form the low-temperature three-dimensional growth layer 12A (FIG. 2C, a period T17 in FIG. 3). In FIG. 3, a case at a temperature of 1000° C. is shown as an example. The pressure is the same as in the previous step. When the nuclei 11A are combined, it is possible to reduce the threading dislocations and to form a high-quality low-temperature three-dimensional growth layer 12A.

Here, since the growth temperature of the low-temperature three-dimensional growth layer 12A is a temperature lower than the growth temperature of the nuclei 11A, a stress acting on layers up to the low-temperature three-dimensional growth layer 12A due to a difference in linear expansion coefficient with the substrate 10 becomes a compressive stress. Generally, cracks are generated in the growth layer when the tensile stress is applied. Since the compressive stress is generated due to the difference in linear expansion coefficient in the layers up to the low-temperature three-dimensional growth layer 12A, cracks can be prevented.

When the temperature is decreased, the low-temperature three-dimensional growth layer 12A can be grown slowly, and the combination of the low-temperature three-dimensional growth layers 12A growing from the nuclei 11A can also proceed slowly. There is a possibility that the tensile stress is generated when the three-dimensional nuclei 11A are combined to form a two-dimensional flat film. However, as described above, since the low-temperature three-dimensional growth layer 12A is grown slowly, even when the low-temperature three-dimensional growth layers 12A on the nuclei 11A are combined to form a continuous film, a three-dimensional surface shape is maintained due to the low-temperature growth, and therefore cracks caused by the tensile stress generated in the film can be prevented.

The low-temperature three-dimensional growth layer 12A is preferably grown to be thicker than the crystal nucleus layer 11, for example, to a thickness of 200 nm to 500 nm. When nucleus shapes are sufficiently combined to a film shape starting from the nuclei 11A, the threading dislocation density can be reduced. Further, the thicker the low-temperature three-dimensional growth layer 12A is, the more uneven the three-dimensional surface can be. Accordingly, lateral growth promoted in subsequent steps can bend the threading dislocation, and the number of threading dislocations propagating to the surface of the growth layer can be reduced. The thickness is more preferably 250 nm to 400 nm, and still more preferably 250 nm to 350 nm.

The growth temperature of the low-temperature three-dimensional growth layer 12A is preferably 900° C. to 1100° C. When the growth temperature is 900° C. or higher, impurities are less likely to enter the crystal, and light absorption can be reduced. The growth temperature is more preferably 950° C. to 1050° C., and still more preferably 975° C. to 1025° C.

The low-temperature three-dimensional growth layer 12A has a growth rate smaller than the growth rate of the crystal nucleus layer 11. When the growth rate is smaller and the combination slowly proceeds starting from the nuclei 11A, the dislocations can be effectively reduced. In addition, the formation of the tensile stress generated when the nuclei 11A are combined to form a continuous film can be relaxed. The growth rate is preferably 2 nm/min to 20 nm/min. The growth rate is more preferably 2 nm/min to 15 nm/min, and still more preferably 2 nm/min to 10 nm/min.

In addition, the low-temperature three-dimensional growth layer 12A has a V/III ratio larger than the V/III ratio of the crystal nucleus layer 11, which is preferably 500 to 2000. The growth rate can be controlled within the above range. The V/III ratio is more preferably 750 to 1750, and still more preferably 1000 to 1500.

### 1-6. High-Temperature Three-Dimensional Growth Layer Forming Step

After the low-temperature three-dimensional growth layers 12A grown starting from the nuclei 11A are sufficiently combined and the low-temperature three-dimensional growth layer 12A has grown to a predetermined thickness, a high-temperature three-dimensional growth layer 12B is formed by further growing on the low-temperature three-dimensional growth layer 12A at a growth temperature higher than that in the step of forming the low-temperature three-dimensional growth layer 12A and equal to or lower than the growth temperature in the step of forming the crystal nucleus layer 11 (FIG. 2D). The pressure is the same as in the previous step.

The high-temperature three-dimensional growth layer 12B is a layer grown to allow a smooth transition from three-dimensional growth of the low-temperature three-dimensional growth layer 12A to two-dimensional growth of the two-dimensional growth layer 13. The high-temperature three-dimensional growth layer 12B is obtained by three-dimensional growth in which lateral growth is faster than that of the low-temperature three-dimensional growth layer 12A. Since the high-temperature three-dimensional growth layer 12B has a growth temperature higher than that of the low-temperature three-dimensional growth layer 12A, the lateral growth is faster than that of the low-temperature three-dimensional growth layer 12A, and the crystals can be more effectively combined. As a result, by bending the threading dislocations laterally, the number of threading dislocations propagating to the surface direction can be reduced, and a crystal film having a small threading dislocation density is obtained.

Here, the high-temperature three-dimensional growth layer 12B is formed at a temperature higher than that of the low-temperature three-dimensional growth layer 12A, and a difference in linear expansion coefficient with the substrate 10 generates a tensile stress in the crystal layer up to the high-temperature three-dimensional growth layer 12B compared to the growth of the low-temperature three-dimensional growth layer 12A. Therefore, the high-temperature three-dimensional growth layer 12B is preferably grown not as a completely flat film but as a three-dimensional surface partially having pits or facets, so that the tensile stress generated on the surface is relaxed to allow growth.

The high-temperature three-dimensional growth layer 12B is preferably grown to be thicker than the low-temperature three-dimensional growth layer 12A, for example, to a thickness of 750 nm to 2000 nm. Within this range, the threading dislocation density can be further reduced by further promoting the crystal combination. The thickness is more preferably 1000 nm to 1750 nm, and still more preferably 1250 nm to 1500 nm.

The growth temperature of the high-temperature three-dimensional growth layer 12B is preferably 1050° C. to 1200° C. Within such a range, the growth mode can be efficiently converted from the three-dimensional growth to the two-dimensional growth. The growth temperature is more preferably 1075° C. to 1175° C., and still more preferably 1100° C. to 1150° C.

The high-temperature three-dimensional growth layer 12B has a growth rate larger than the growth rate of the low-temperature three-dimensional growth layer 12A and equal to or smaller than the growth rate of the crystal nucleus layer 11, which is preferably 5 nm/min to 50 nm/min. When the growth rate is within this range, the crystals are slowly combined, a change in tensile stress generated on the surface of the crystal layer is relaxed, so that the generation of cracks when the crystals are combined can be prevented. The growth rate is more preferably 10 nm/min to 40 nm/min, and still more preferably 15 nm/min to 30 nm/min.

The high-temperature three-dimensional growth layer 12B has a V/III ratio smaller than the V/III ratio of the low-temperature three-dimensional growth layer 12A and equal to or larger than the V/III ratio of the crystal nucleus layer 11, which is preferably 100 to 1000. The growth rate can be controlled within the above range. The V/III ratio is more preferably 150 to 700, and still more preferably 200 to 500.

### 1-7. Two-Dimensional Growth Layer Forming Step

After the high-temperature three-dimensional growth layer 12B has grown to a predetermined thickness, the two-dimensional growth layer 13 made of AlN containing Ga or AlGaN is formed at a temperature same as or higher than that in the step of forming the high-temperature three-dimensional growth layer 12B by supplying TMGa in addition to ammonia and TMAl (see FIG. 2E). The pressure is the same as in the previous step.

When Ga is supplied during the growth of AlN, the growth mode of AlN is two-dimensional growth in which lateral growth is promoted with Ga atoms, which have surface migration higher than that of Al atoms. Therefore, the two-dimensional growth layer 13 allows the crystal to be flattened. A supply amount of Ga is increased continuously and stepwise over time. Accordingly, when the lateral growth rate is slowly increased to relax the change in tensile stress generated when the crystals are combined, the generation of cracks in the two-dimensional growth layer 13 can be prevented.

The supply amount of Ga is controlled based on a molar ratio of TMGa to TMAl. The molar ratio of TMGa to TMAl is preferably 0.05 to 0.5, more preferably 0.08 to 0.4, and still more preferably 0.1 to 0.3.

Although the ratio of TMGa is very high, Ga is not actually incorporated into AlN at the above ratio. This is because the Ga atoms evaporate more easily than the Al atoms on the AlN surface, so that the amount of Ga atoms actually incorporated into the AlN crystal is only a few percent even when the molar ratio of the raw material gas is 0.3. As the growth temperature increases, the Ga atoms evaporate preferentially, and therefore fewer Ga atoms are incorporated into the AlN crystal. Although it depends on conditions such as the growth temperature, a Ga solid phase ratio in Al₁₋ₓGaₓN grown in the above molar ratio range is x=about 0.01% to 0.1%.

By applying a continuous, stepwise gradient within the above molar ratio range, the supply amount of Ga is increased in gradient over time. By supplying Ga, the two-dimensional growth layer 13 changes from AlN to a mixed crystal (Al₁₋ₓGaₓN) of AlN and GaN. Here, the Ga composition is preferably 0.01 to 0.1.

The two-dimensional growth layer 13 is preferably grown to have a thickness equal to or larger than that of the high-temperature three-dimensional growth layer 12B, for example, to a thickness of 750 nm to 2000 nm. Within this range, the surface of the two-dimensional growth layer 13 can be sufficiently flattened. For example, a surface roughness RMS can be 0.5 nm to 5 nm. The thickness is more preferably 1000 nm to 1750 nm, and still more preferably 1250 nm to 1500 nm.

The growth temperature of the two-dimensional growth layer 13 is preferably 1100° C. to 1200° C. When the temperature is within this range, the two-dimensional growth layer 13 can be sufficiently flattened. The growth temperature is more preferably 1120° C. to 1190° C., and still more preferably 1140° C. to 1180° C. The temperature may be the same as that in the step of forming the crystal nucleus layer 11 and the step of forming the high-temperature three-dimensional growth layer 12B.

The two-dimensional growth layer 13 has a growth rate equal to or larger than the growth rate of the high-temperature three-dimensional growth layer 12B and equal to or smaller than the growth rate of the crystal nucleus layer 11, which is preferably 5 nm/min to 50 nm/min. When the growth rate is within this range, the growth rate is sufficiently small, the change in tensile stress due to the flattening of the crystal can be relaxed, and the generation of cracks can be prevented. The growth rate is more preferably 10 nm/min to 40 nm/min, and still more preferably 15 nm/min to 30 nm/min.

The two-dimensional growth layer 13 has a V/III ratio equal to or smaller than the V/III ratio of the high-temperature three-dimensional growth layer 12B and equal to or larger than the V/III ratio of the crystal nucleus layer 11, which is preferably 50 to 500. The growth rate can be controlled within the above range. The V/III ratio is more preferably 100 to 400, and still more preferably 150 to 300.

Thereafter, a semiconductor layer may be continuously grown on the two-dimensional growth layer 13 to prepare an element such as a light emitting element, or the production may be ended at the stage where the two-dimensional growth layer 13 is grown and this layer may be used as a template substrate. In addition, the substrate 10 may be peeled off by laser lift-off (LLO) and used as a template.

In the first embodiment, the switching of the period from the formation of the nuclei 11A to the formation of the two-dimensional growth layer 13 is controlled based on the growth temperature, but it may also be controlled based on the growth rate. The growth rate can be controlled, for example, based on the growth temperature and the V/III ratio.

As described above, with the method for producing a Group III nitride semiconductor according to the first embodiment, the crystal quality of the crystal nucleus layer 11 can be improved. The reason for the improvement in crystal quality is not clear, but can be assumed as follows. It is thought that when the ammonia treatment is performed before the thermal cleaning, some modification occurs on the surface of the substrate 10 since ammonia is corrosive. Therefore, it is thought that the effect of removing impurities, oxides, or particles from the surface of the substrate 10 during the thermal cleaning is improved. In this way, it is thought that, as a result of further reducing impurities on the surface of the substrate 10, good-quality AlN can be formed on the surface of the substrate 10 in the nitriding treatment after the thermal cleaning, and the crystal quality of the crystal nucleus layer 11 formed on the AlN is also improved.

### 2. Experiment Results

Next, various experiment results according to the first embodiment will be described.

### Experiment 1

The substrate 10 was successively subjected to an ammonia treatment, thermal cleaning, and a nitriding treatment, and then the crystal nucleus layer 11, the low-temperature three-dimensional growth layer 12A, the high-temperature three-dimensional growth layer 12B, and the two-dimensional growth layer 13 were formed on the substrate 10 in this order from the substrate 10 side to prepare a sample. Three types of samples were prepared by changing the temperature range in the ammonia treatment. For comparison, a sample was also similarly prepared except that the ammonia treatment was not performed.

The temperature and the pressure were as shown in the graph in FIG. 3. The crystal nucleus layer 11 was grown at a growth rate of 30 nm/min and to a thickness of 50 nm, the low-temperature three-dimensional growth layer 12A was grown at a growth rate of 4 nm/min and to a thickness of 250 nm, the high-temperature three-dimensional growth layer 12B was grown at a growth rate of 18 nm/min and to a thickness of 1300 nm, and the two-dimensional growth layer 13 was grown at a growth rate of 18 nm/min and to a thickness of 1400 nm. In the two-dimensional growth layer 13, the molar ratio of TMGa to TMAl was continuously changed from 13% to 30%.

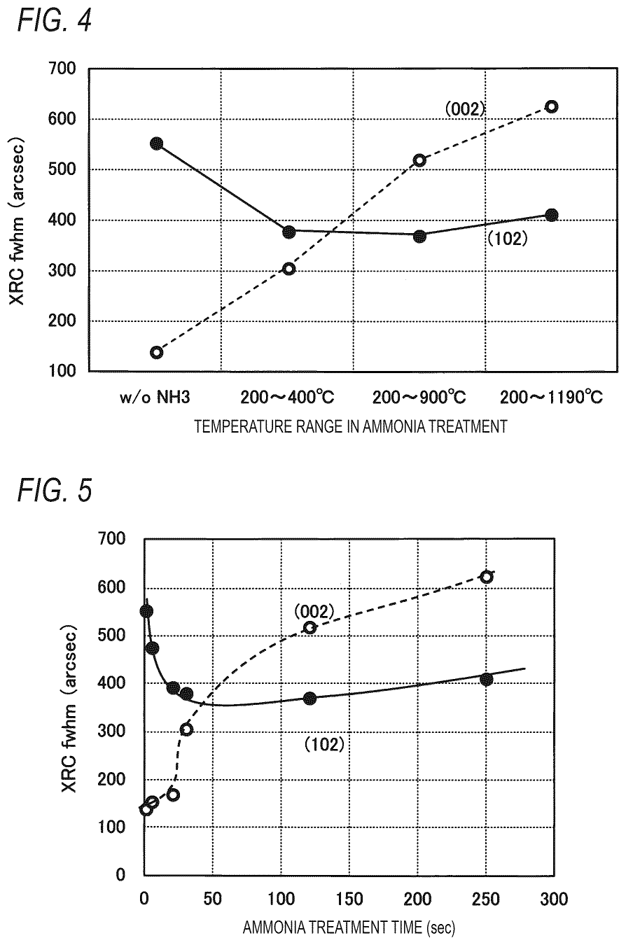

Rocking curve measurement in X-ray diffraction of the two-dimensional growth layer 13 of the prepared sample was performed, and the full widths at half maximum (FWHM) of a (002) diffraction line and a (102) diffraction line were determined. FIG. 4 is a graph showing a relationship between the temperature range in the ammonia treatment and the full width at half maximum. The temperature range in the ammonia treatment is three: a case where the temperature is increased from 200° C. to 400° C., a case where the temperature is increased from 200° C. to 900° C., and a case where the temperature is increased from 200° C. to 1190° C.

As shown in FIG. 4, in the (102) diffraction line, in all the temperature ranges, the full width at half maximum is smaller than that without an ammonia treatment. In addition, when the temperature is increased from 200° C. to 1190° C., the full width at half maximum is slightly larger than in other temperature ranges. In the (002) diffraction line, the wider the temperature range and the higher the maximum temperature, the larger the full width at half maximum. This result shows that in order to improve the crystal quality of the two-dimensional growth layer 13, the temperature range is preferably 200° C. to 400° C., or 200° C. to 900° C. This result also shows that the ammonia treatment is preferably performed at 900° C. or lower.

### Experiment 2

Samples were prepared in the same manner as in Experiment 1, but with the treatment time in the ammonia treatment being changed in various ways. The ammonia treatment time was the time required to increase the temperature from 200° C., and the temperature increase rate was 3° C./s to 5° C./s. Then, the full widths at half maximum (FWHM) of the (002) diffraction line and the (102) diffraction line were determined in the same manner as in Experiment 1.

FIG. 5 is a graph showing a relationship between the treatment time in the ammonia treatment and the full width at half maximum. As shown in FIG. 5, in the (102) diffraction line, when the treatment time is equal to or shorter than about 60 seconds, the full width at half maximum decreases greatly as the treatment time increases, and when the treatment time is longer than 60 seconds, the full width at half maximum increases gradually as the treatment time increases. In the (002) diffraction line, the full width at half maximum increases as the treatment time increases. This result shows that in order to improve the crystal quality, the treatment time in the ammonia treatment is preferably 1 second to 60 seconds.

### Experiment 3

Samples were prepared in the same manner as in Experiment 1, but with the start temperature in the ammonia treatment being changed in various ways. Note that, the temperature increase time in the ammonia treatment was 20 seconds, and the temperature increase rate was the same as in Experiment 2. Then, the full widths at half maximum (FWHM) of the (002) diffraction line and the (102) diffraction line were determined in the same manner as in Experiment 1.

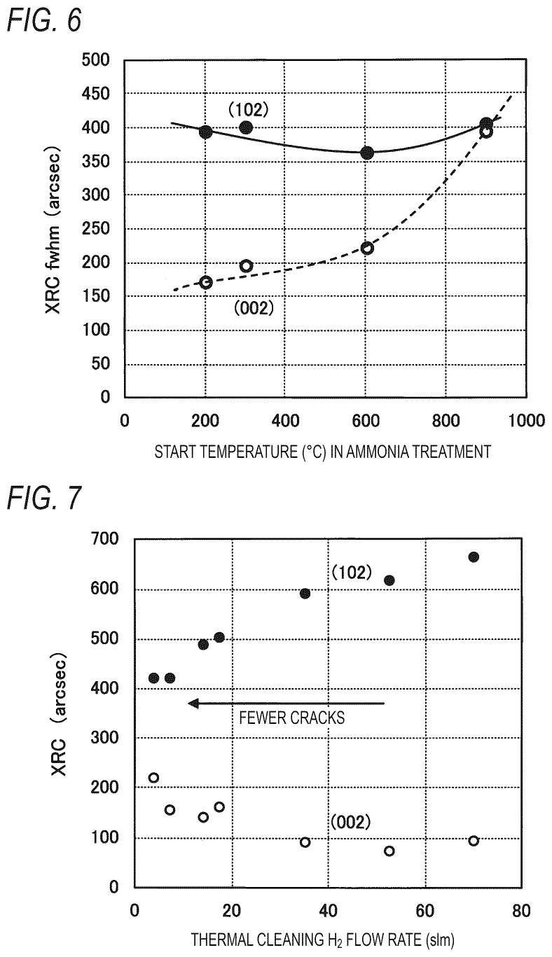

FIG. 6 is a graph showing a relationship between the start temperature in the ammonia treatment and the full width at half maximum. As shown in FIG. 6, in the (102) diffraction line, up to about 700° C., the full width at half maximum decreases as the temperature increases, and at higher than 700° C., the full width at half maximum increases as the temperature increases. In the (002) diffraction line, up to about 700° C., the full width at half maximum gradually increases as the temperature increases, and at higher than 700° C., the full width at half maximum greatly increases as the temperature increases. This result shows that in order to improve the crystal quality, the start temperature in the ammonia treatment is preferably 100° C. to 700° C.

### Experiment 4

Samples were prepared in the same manner as in Experiment 1, but with the flow rate of a hydrogen gas in the thermal cleaning being changed in various ways. Then, the full widths at half maximum (FWHM) of the (002) diffraction line and the (102) diffraction line were determined in the same manner as in Experiment 1.

FIG. 7 is a graph showing a relationship between the flow rate of the hydrogen gas in the thermal cleaning and the full width at half maximum. As shown in FIG. 7, in the (102) diffraction line, the full width at half maximum increases as the flow rate increases. In the (002) diffraction line, the full width at half maximum decreases as the flow rate increases. In addition, the number of cracks in the two-dimensional growth layer 13 decreases as the flow rate decreases. This result shows that in order to improve the crystal quality, the flow rate of hydrogen in the thermal cleaning is preferably 1 slm to 30 slm.

### Experiment 5

Samples were prepared in the same manner as in Experiment 1, but with the treatment time in the nitriding treatment being changed in various ways. Then, the full widths at half maximum (FWHM) of the (002) diffraction line and the (102) diffraction line were determined in the same manner as in Experiment 1.

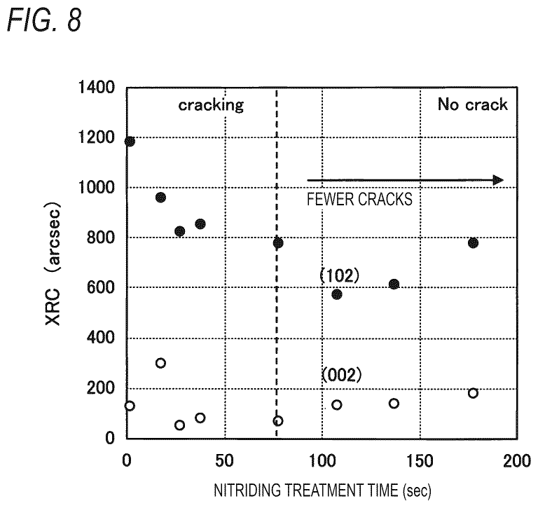

FIG. 8 is a graph showing a relationship between the treatment time in the nitriding treatment and the full width at half maximum. As shown in FIG. 8, in the (102) diffraction line, up to about 120 seconds, the full width at half maximum decreases as the treatment time increases, and at longer than 120 seconds, the full width at half maximum increases as the treatment time increases. In the (002) diffraction line, the full width at half maximum gradually increases as the treatment time increases. In addition, when the treatment time is 50 seconds or longer, the number of cracks in the two-dimensional growth layer 13 decreases as the treatment time is longer, and when the treatment time is 150 seconds or longer, no cracks are generated. This result shows that in order to improve the crystal quality, the treatment time in the nitriding treatment is preferably 70 seconds or longer.

### Modification of First Embodiment

As the nuclei 11A in the first embodiment, AlGaN or GaN may be used instead of AlN. When GaN or AlGaN is used, a difference in lattice constant with the sapphire substrate 10 is increased, and the strain relaxation at the interface between the substrate 10 and the nuclei 11A is increased. In addition, when the nuclei 11A are made of AlGaN or GaN, the lattice constant of the low-temperature three-dimensional growth layer 12A formed thereon is larger in Al composition than that of the nuclei 11A, so that the low-temperature three-dimensional growth layer 12A growing on the nuclei 11A is subjected to a tensile strain. This is because the growing crystals form in a manner of matching the lattice constant of the substrate. Therefore, this can relax the compressive strain generated in the low-temperature three-dimensional growth layer 12A and subsequent layers due to a thermal stress in the substrate and the crystal layer generated when the growth is completed and the temperature is room temperature.

In addition, due to the strain relaxation at the interface between the substrate 10 and the nuclei 11A, the nuclei 11A are formed discretely rather than in a film shape, so that the generation of cracks is prevented. In addition, the low-temperature three-dimensional growth layer 12A formed on the crystal nucleus layer 11 receives the tensile stress from the crystal nucleus layer 11 due to the difference in lattice constant, but the generation of cracks due to the tensile stress is prevented due to the three-dimensional growth. As a result of the above, the threading dislocation density of the two-dimensional growth layer 13 can be reduced.

In addition, when the nuclei 11A are made of GaN or AlGaN, a surfactant effect of Ga allows the nuclei 11A to be enlarged, and the nucleus density can be reduced. As described above, a small nucleus density can reduce the tensile stress generated on the surface when the nuclei are combined into a flat film. In addition, the number of combining surfaces where the nuclei 11A are combined is reduced, the formation of the threading dislocations can be reduced, and a high-quality crystal film can be formed.

The nuclei 11A may be made of GaN doped with Al. The nuclei 11A are preferably made of AlGaN rather than GaN, and the Al composition is preferably 60% or more and 98% or less. The strain can be further relaxed, and the nuclei 11A can be further enlarged. The Al composition is more preferably 60% or more and 98% or less.

When the nuclei 11A are made of GaN or AlGaN, the substrate 10 is easily separated by laser lift-off. That is, since band gap energy is smaller than that of AlN, it is easier to cause the crystal nucleus layer 11 to absorb laser light. In addition, since Ga has a melting point that is much lower than that of Al, Ga becomes liquid when the crystal nucleus layer 11 is decomposed by irradiation with laser light. Therefore, when the crystal nucleus layer 11 contains Ga, the substrate 10 can be easily separated. In this way, when the nuclei 11A are made of GaN or AlGaN, the crystal nucleus layer 11 is effective as a sacrificial layer in laser lift-off.

When the nuclei 11A are made of GaN or AlGaN, the size of the nuclei 11A is preferably 20 nm to 100 nm. When the size of the nuclei 11A is within this range, the tensile stress can be sufficiently reduced. In addition, a variation in size of the nuclei 11A (a difference between a maximum diameter and the average diameter, and a difference between the average diameter and a minimum diameter) is preferably 20 nm or less.

In addition, when the nuclei 11A are made of GaN or AlGaN, the thickness of the crystal nucleus layer 11 is preferably 5 nm to 100 nm. Since the nuclei 11A are larger than in the case where the nuclei 11A are made of AlN, the crystal nucleus layer 11 also becomes thicker. As a result of the nuclei 11A being larger, the quality of the crystal layer formed after the nuclei 11A can be further improved. The thickness of the crystal nucleus layer 11 is more preferably 5 nm to 50 nm. When the nuclei 11A are made of AlGaN and the Ga composition is high, the crystal is more mobile by annealing, and it is easier to enlarge the nuclei 11A by solid phase growth. With the annealing, the size of the nuclei 11A immediately before the three-dimensional growth layer is grown can be increased to reduce the density.

In addition, when the nuclei 11A are made of GaN or AlGaN, the density of the nuclei 11A is preferably 3×10¹¹/cm⁻² or less. Since the nuclei 11A are larger than in the case of AlN, the density of the nuclei 11A is also smaller than in the case of AlN. The nucleus density is more preferably 1.5×10¹¹/cm⁻² or less, and more preferably 1×10¹¹/cm⁻² or less. In addition, when the nuclei 11A are made of GaN or AlGaN, the nuclei 11A can be enlarged by annealing. That is, the nucleus density can be 1×10¹¹/cm⁻² or less.

In addition, in the first embodiment, the low-temperature three-dimensional growth layer 12A is made of AlN, but is not limited to AlN and may be made of AlGaN. However, in terms of strain relaxation and crystallinity, a difference between the Al composition of the low-temperature three-dimensional growth layer 12A and the Al composition of the crystal nucleus layer 11 is preferably 40% or less.

In addition, in the first embodiment, the high-temperature three-dimensional growth layer 12B is made of AlN, but is not limited to AlN and may be made of AlGaN. However, in terms of strain relaxation and crystallinity, a difference between the Al composition of the high-temperature three-dimensional growth layer 12B and the Al composition of the low-temperature three-dimensional growth layer 12A is preferably 30% or less.

In addition, in the first embodiment, the two-dimensional growth layer 13 is made of AlN, but is not limited to AlN and may be made of AlGaN. However, in terms of strain relaxation and crystallinity, a difference between the Al composition of the two-dimensional growth layer 13 and the Al composition of the high-temperature three-dimensional growth layer 12B is preferably 20% or less.

In addition, when a device to be formed on the two-dimensional growth layer 13 is a light emitting device, crystal layers below the two-dimensional growth layer 13 need to have an Al composition that does not absorb light. When the device to be formed on the two-dimensional growth layer 13 is an ultraviolet emitting LED, the Al composition of the two-dimensional growth layer 13 is preferably equal to or larger than the Al composition of an n-type layer of the LED.

For the above reasons, most of the device structure is often formed with an Al composition smaller than the Al composition of the two-dimensional growth layer 13. In order to relax the strain of the device structure, it is preferable to change the difference in lattice mismatch stepwise. It is preferable that the Al compositions of the three-dimensional growth layer 12 and subsequent layers, excluding the crystal nucleus layer 11, decrease stepwise. In this way, the strain applied to the device structure can be relaxed.

When the Al composition of the nuclei 11A decreases, the lattice constant changes from AlN to that of GaN. That is, the in-plane lattice constant is increased. Therefore, the three-dimensional growth layer 12 formed on the nuclei 11A and having an Al composition larger than that the Al composition the nuclei 11A receives the tensile strain from the nuclei 11A. When the Al composition of the nuclei 11A decreases, the in-plane lattice constant of the three-dimensional growth layer 12 tends to be increased. When the growing three-dimensional growth layer 12 receives the tensile strain, the possibility of crack formation increases, so that there is an optimum value for the difference in Al composition between the nuclei 11A and the three-dimensional growth layer 12, as described above. When the growth is completed and the temperature is room temperature, the tensile strain formed in the three-dimensional growth layer 12 and subsequent layers during growth becomes a compressive strain due to the difference in thermal expansion coefficient with the substrate 10 made of sapphire. However, similar to the growth, as the lattice constant of the nuclei 11A increases, the compressive strain generated in the three-dimensional growth layer 12 and subsequent layers at room temperature is relaxed.

In addition, when the nuclei 11A are made of GaN or AlGaN, the thickness of the two-dimensional growth layer 13 is preferably 0.5 μm to 5 μm. The surface of the two-dimensional growth layer 13 can be sufficiently flattened. For example, the surface roughness RMS can be 0.5 nm to 2 nm. The thickness of the two-dimensional growth layer 13 is preferably 1 μm to 3 μm.

In addition, even when the nuclei 11A are made of GaN or AlGaN, the threading dislocation density of the two-dimensional growth layer 13 can be 5×10¹¹ cm⁻² or less, and a good-quality crystal can be obtained. In addition, in the rocking curve measurement in the X-ray diffraction of the two-dimensional growth layer 13, the full width at half maximum (FWHM) of the (002) diffraction line can be, for example, 100 arcsec to 300 arcsec, and the full width at half maximum of the (102) diffraction line can be, for example, 300 arcsec to 600 arcsec. This is because the full width at half maximum can be sufficiently reduced by reducing the threading dislocation density.

Note that, when the nuclei 11A are made of GaN or AlGaN, the growth conditions such as the growth temperature and the growth rate of each layer can be in the same range as in the first embodiment.

### Second Embodiment

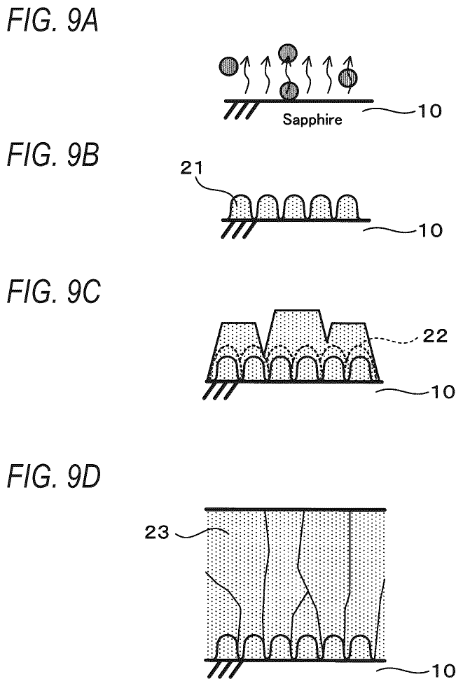

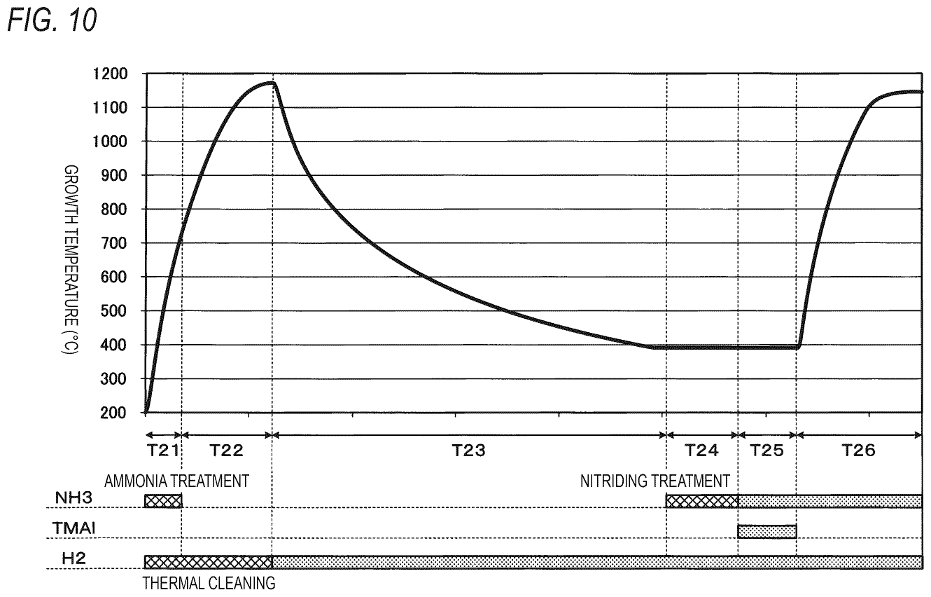

A method for producing a Group III nitride semiconductor according to a second embodiment will be described. In the description of the production method, reference will be made to FIGS. 9A, 9B, 9C, and 9D and FIG. 10 as appropriate. FIGS. 9A, 9B, 9C, and 9D are diagrams each schematically showing a layer configuration in each growth stage up to formation of a two-dimensional growth layer 23. FIG. 10 is a graph showing a change in temperature over time and supply timings of various gases.

In the method for producing a Group III nitride semiconductor according to the second embodiment, first, the surface of the substrate 10 is subjected to an ammonia treatment (a period T21 in FIG. 10), and then subjected to thermal cleaning (FIG. 9A, a period T22 in FIG. 10). Various conditions for the ammonia treatment and the thermal cleaning are the same as those in the first embodiment.

Next, the substrate 10 is cooled to a temperature for the subsequent nitriding treatment step (a period T23 in FIG. 10), and then subjected to the nitriding treatment (a period T24 in FIG. 10). The temperature is, for example, 350° C. to 650° C. In FIG. 10, a case where the treatment is performed at 390° C. is shown as an example. The nitriding treatment may be performed during cooling. This nitriding treatment can be performed under the conditions same as those in the nitriding treatment in the first embodiment excluding the temperature.

Next, ammonia and TMAl are supplied at a temperature same as that in the previous nitriding treatment step, and nuclei 21A of AlN are generated on the substrate 10 to form a crystal nucleus layer 21 (FIG. 9B, a period T25 in FIG. 10). Note that, the temperature may be different from that in the nitriding treatment so long as it is within the range of 350° C. to 650° C.

Next, the temperature is increased to a growth temperature of a three-dimensional growth layer 22 (a period T26 in FIG. 10), and the nuclei 21A of the crystal nucleus layer 21 are annealed to promote solid phase growth and are changed into columnar shapes. The temperature is increased to, for example, 1100° C. to 1200° C. Then, ammonia and TMGa are supplied to grow GaN three-dimensionally on the crystal nucleus layer 21 to form the three-dimensional growth layer 22.

Next, GaN is grown two-dimensionally on the three-dimensional growth layer 22 at a temperature higher than that in the growth of the three-dimensional growth layer 22, to form the two-dimensional growth layer 23. When the growth temperature is increased, promoting the migration of the raw material is promoted and the lateral growth is accelerated, whereby the two-dimensional growth can be achieved. Instead of increasing the temperature, when the V/III ratio is increased, the lateral growth may be accelerated and the two-dimensional growth may be achieved.

Note that, in the second embodiment, GaN is grown as the three-dimensional growth layer 22 and the two-dimensional growth layer 23, but any Group III nitride semiconductor may be used. However, AlGaN having a small Al composition is preferred. For example, it is AlGaN having an Al composition of 20% or less. Particularly preferred is GaN as in the second embodiment. Unlike AlGaN or AlN having a large Al composition, the lateral growth of AlGaN or GaN having a small Al composition is easy to control based on the temperature or the V/III ratio. This is because Ga migrates faster than Al. Therefore, even when the three-dimensional growth layer has large irregularities, it can be easily flattened by using the two-dimensional growth layer.

As described above, in the method for producing a Group III nitride semiconductor according to the second embodiment, since the ammonia treatment is performed before the thermal cleaning and the nitriding treatment is performed after the thermal cleaning, the crystal quality of the crystal nucleus layer 21 can be improved even when the crystal nucleus layer 21 is formed at a low temperature. Therefore, the crystal quality of the Group III nitride semiconductor, particularly GaN, formed on the crystal nucleus layer 21 can be improved.

Next, various experiment results according to the second embodiment will be described. The substrate 10 was successively subjected to an ammonia treatment, thermal cleaning, and a nitriding treatment, and then the crystal nucleus layer 21, the three-dimensional growth layer 22, and the two-dimensional growth layer 23 were formed on the substrate 10 in this order from the substrate 10 side to prepare a sample (hereinafter, referred to as an example). For comparison, a sample was prepared in the same manner as in the example except that the ammonia treatment was not performed (hereinafter, referred to as a comparative example). The temperature was as shown in the graph in FIG. 10.

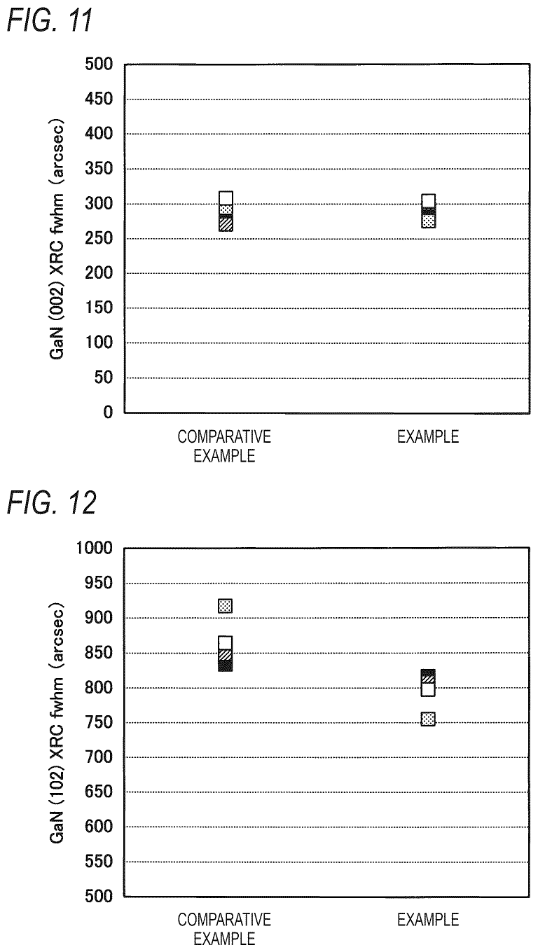

Rocking curve measurement in X-ray diffraction of the two-dimensional growth layer 23 of the prepared sample was performed, and the full widths at half maximum (FWHM) of the (002) diffraction line and the (102) diffraction line were determined. FIGS. 11 and 12 are graphs comparing the full widths at half maximum of the example and the comparative example, in which FIG. 11 shows the full width at half maximum of the (002) diffraction line, and FIG. 12 shows the full width at half maximum of the (102) diffraction line.

As shown in FIG. 11, there is no great change in full width at half maximum of the (002) diffraction line between the example and the comparative example. On the other hand, the full width at half maximum of the (102) diffraction line is smaller in the example than in the comparative example. This result shows that when the ammonia treatment is performed before the thermal cleaning and the nitriding treatment is performed after the thermal cleaning, the crystal quality can be improved even when the crystal nucleus layer 21 is formed at a low temperature. It has been found that although the effect of increasing the full width at half maximum is smaller than that in the first embodiment, the same effect can be obtained even when the growth temperature of the nuclei 21A is a low temperature. A comparison between the first embodiment and the second embodiment shows that forming high-quality nuclei at a high temperature may be more effective in treating the substrate surface by an ammonia treatment, thermal cleaning, and a nitriding treatment.

What is claimed is:

1. A method for producing a Group III nitride semiconductor, comprising:
performing an ammonia treatment of supplying a gas containing ammonia to a surface of a substrate containing sapphire;
subjecting the surface of the substrate to a heat treatment in a hydrogen-dominated atmosphere, after the ammonia treatment;
nitriding the surface of the substrate by supplying a gas containing ammonia to the surface of the substrate, after the subjecting; and
forming a crystal nucleus layer on the substrate by generating nuclei of GaN, AlGaN or AlN on the substrate, after the nitriding.

2. The method for producing a Group III nitride semiconductor according to claim 1, wherein the ammonia treatment is performed at a temperature of 20° C. or higher and 900° C. or lower.

3. The method for producing a Group III nitride semiconductor according to claim 1, wherein the ammonia treatment is performed for a time of 1 second or longer and 60 seconds or shorter.

4. The method for producing a Group III nitride semiconductor according to claim 1, wherein the ammonia treatment is performed under a partial pressure of the ammonia of 0.001 atm or more and 0.1 atm or less and at a linear velocity of the gas of 0.01 m/min or more and 300 m/min or less.

5. The method for producing a Group III nitride semiconductor according to claim 1, wherein the heat treatment is performed at a temperature higher than 900° C.

6. The method for producing a Group III nitride semiconductor according to claim 1, wherein the nitriding is performed at a temperature equal to or lower than a temperature in the heat treatment for 70 seconds or longer.

7. The method for producing a Group III nitride semiconductor according to claim 1, further comprising:
forming a low-temperature three-dimensional growth layer by growing AlGaN or AlN from each of the nuclei to form crystals at a temperature lower than a temperature in the forming of the crystal nucleus layer and combining the crystals from adjacent ones of the nuclei, after the forming of the crystal nucleus layer; and
forming a high-temperature three-dimensional growth layer by growing AlGaN or AlN from the low-temperature three-dimensional growth layer at a temperature higher than the temperature in the forming of the low-temperature three-dimensional growth layer and equal to or lower than the temperature in the forming of the crystal nucleus layer, after the forming of the low-temperature three-dimensional growth layer.
